(19) United States
(12) Patent Application Publication
(10) Pub. No.: US 2004/0072081 A1
(43) Pub. Date: Apr. 15, 2004

(54) Methods for etching photolithographic reticles

(76) Inventors: Thomas P. Coleman, Aix en Provence (FR); Yi-Chiau Huang, Fremont, CA (US); Melisa J. Buie, San Jose, CA (US); Lawrence C. Sheu, San Diego, CA (US); Brigitte C. Stoehr, San Jose, CA (US); Phillip L. Jones, Fremont, CA (US)

Correspondence Address: PATENT COUNSEL, APPLIED MATERIALS, INC., Legal Affairs Department, P.O.BOX 450A, Santa Clara, CA, 95052, US

(21) Appl. No.: 10/437,729

(22) Filed: May 13, 2003

Related U.S. Application Data
(60) Provisional application No. 60/380,493, filed on May 14, 2002.

(51) Int. Cl. G03F 9/00; H01L 21/31; H01L 21/469

(52) U.S. Cl. 430/5; 438/791; 438/792; 438/793

(57) ABSTRACT

Method and apparatus for etching an optically transparent layer disposed on a substrate, such as a photolithographic reticle, are provided. In one aspect, a method is provided for etching a substrate comprising placing the reticle on a support member in a processing chamber, positioning the reticle on a support member in a processing chamber, wherein the reticle comprises a patterned metal photomask layer formed on an optically transparent material, and a patterned resist material deposited on the patterned metal photomask layer, introducing a processing gas comprising one or more fluorine containing hydrocarbons and one or more chlorine-containing gases into the processing chamber, delivering power to the processing chamber to generate a plasma by applying a source RF power to a coil and applying a bias power to the support member, and etching exposed portions of the optically transparent material.

### CROSS-REFERENCE TO RELATED APPLICATIONS

This application claims benefit of United States provisional patent application serial No. 60/380,493, filed May 14, 2002, which is herein incorporated by reference.

### BACKGROUND OF THE INVENTION

1. Field of the Invention

The invention relates to the fabrication of integrated circuits and to the fabrication of photomasks useful in the manufacture of integrated circuits.

2. Background of the Related Art

Semiconductor device geometries have dramatically decreased in size since such devices were first introduced several decades ago. Since then, integrated circuits have generally followed the two year/half-size rule (often called Moore's Law), which means that the number of devices on a chip doubles every two years. Today's fabrication plants are routinely producing devices having 0.15 μm and even 0.13 μm feature sizes, and tomorrow's plants soon will be producing devices having even smaller geometries.

The increasing circuit densities have placed additional demands on processes used to fabricate semi-conductor devices. For example, as circuit densities increase, the widths of vias, contacts and other features, as well as the dielectric materials between them, decrease to sub-micron dimensions, whereas the thickness of the dielectric layers remains substantially constant, with the result that the aspect ratios for the features, i.e., their height divided by width, increases. Reliable formation of high aspect ratio features is important to the success of sub-micron technology and to the continued effort to increase circuit density and quality of individual substrates.

High aspect ratio features are conventionally formed by patterning a surface of a substrate to define the dimensions of the features and then etching the substrate to remove material and define the features. To form high aspect ratio features with a desired ratio of height to width, the dimensions of the features are required to be formed within certain parameters, which are typically defined as the critical dimensions of the features. Consequently, reliable formation of high aspect ratio features with desired critical dimensions requires precise patterning and subsequent etching of the substrate.

Photolithography is a technique used to form precise patterns on the substrate surface and then the patterned substrate surface is etched to form the desired device or features. Photolithography techniques use light patterns and resist materials deposited on a substrate surface to develop precise patterns on the substrate surface prior to the etching process. In conventional photolithographic processes, a resist is applied on the layer to be etched, and the features to be etched in the layer, such as contacts, vias, or interconnects, are defined by exposing the resist to a pattern of light through a photolithographic reticle having a photomask layer disposed thereon. The photomask layer corresponds to the desired configuration of features. A light source emitting ultraviolet (UV) light or low X-ray light, for example, may be used to expose the resist to alter the composition of the resist. Generally, the exposed resist material is removed by a chemical process to expose the underlying substrate material. The exposed underlying substrate material is then etched to form the features in the substrate surface while the retained resist material remains as a protective coating for the unexposed underlying substrate material.

Photolithographic reticles typically include a substrate made of an optically transparent material, such as quartz (i.e., silicon dioxide, SiO₂), having an opaque light-shielding layer of metal, typically chromium, disposed on the surface of the substrate. The light-shielding layer is patterned to correspond to the features to be transferred to the substrate. Generally, conventional photolithographic reticles are fabricated by first depositing a thin metal layer on a substrate comprising an optically transparent material, such as quartz, and depositing a resist layer on the thin metal layer. The resist is then patterned using conventional laser or electron beam patterning equipment to define the critical dimensions to be transferred to the metal layer. The metal layer is then etched to remove the metal material not protected by the patterned resist; thereby exposing the underlying material and forming a patterned photomask layer. Photomasks layers allow light to pass therethrough in a precise pattern onto the substrate surface.

In order to achieve current circuit densities, attenuating phase, shift photomasks are being used to increase the precision of the etching pattern formed on the substrate by increasing the resolution of the light passing through the photomask. Attenuating phase shift photomasks are fabricated by depositing a attenuating material layer prior to deposition of the metal photomask layer. The attenuating material layer is then etched using a lithographic process including a resist material to form features that shift the phase of incoming light 180°. The shift in the phase of the light results in a cancellation of light to remove or reduce light detraction and provide improved resolution of the light. To modify the light to produce the desired resolution, the etched features formed in the attenuating material layer of the substrate must be precisely formed in the substrate with a minimal amount of defects in the feature structure.

The attenuating materials are generally silicon based materials, and current etching processes for silicon based materials, such as those materials used for dielectric layers in semi-conductor manufacturing, have proven unsuitable for etching features in attenuating materials.

For example, fluorine-based etch chemistries used to etch silicon based materials have not produced quality photomasks because the chemistry and the processing conditions have not been able to etch acceptable feature definitions. In such an instance, overetching or imprecise etching of the sidewalls of the openings formed in the resist material used to define the critical dimensions of the attenuating material layer. Excess side removal of resist material results in a loss of the critical dimensions of the patterned resist features, which may correspond to a loss of critical dimensions of the features formed in the metal layer defined by the patterned resist layer.

Therefore, there remains a need for a chemistry and process for etching optically transparent materials to minimize defect formation and to form features with straight sidewalls, flat bottoms, high profile angles, and improves etch selectivity.

### SUMMARY OF THE INVENTION

The invention generally provides a method for etching a photolithographic reticle comprising an optically transparent material. In one aspect, a method is provided for etching a substrate including positioning the reticle on a support member in a processing chamber, wherein the reticle comprises an attenuating material layer disposed on an optically transparent material, a patterned metal photomask layer formed on the attenuating material layer, and a patterned resist material deposited on the patterned metal photomask layer, introducing a processing gas comprising one or more fluorine containing polymerizing materials and one or more chlorine-containing gases into the processing chamber, delivering power to the processing chamber to generate a plasma by applying a source RF power to a coil and applying a bias power to the support member, and etching exposed portions of the attenuating material layer.

In another aspect, a method is provided for etching a reticle including an attenuating material layer disposed on an optically transparent material, a patterned metal photomask layer formed on attenuating material layer, and a patterned resist material deposited on the patterned metal photomask layer, the method comprising placing the reticle in a processing chamber on a support member, wherein the reticle is maintained at a temperature of less than about 150° C., introducing a processing gas comprising one or more fluorine containing hydrocarbons have the formula C_{X}H_{Y}F_{Z}, where x is an integer from 1 to 5, y is an integer from 1 to 8, and z is an integer from 1 to 8 and chlorine gas, delivering power to the processing chamber to generate a plasma, and etching exposed portions of the attenuating material layer.

In another aspect, a method is provided for fabricating a reticle for photolithographic processing, comprising patterning a metal layer disposed on an attenuating material layer to expose the attenuating material layer, depositing and patterning a resist layer over the patterned metal layer to expose the attenuating material layer, placing the photomask on a support member in an etch processing chamber, introducing a processing gas comprising one or more fluorine containing polymerizing materials and one or more chlorine-containing gases into the processing chamber, applying a source of RF power to a coil disposed adjacent the etch processing chamber to generate a plasma in the processing chamber, and etching exposed portions of the attenuating material layer.

### BRIEF DESCRIPTION OF THE DRAWINGS

So that the manner in which the above recited features, advantages and objects of the invention are attained and can be understood in detail, a more particular description of the invention, briefly summarized above, may be had by reference to the embodiments thereof which are illustrated in the appended drawings.

It is to be noted, however, that the appended drawings illustrate only typical embodiments of this invention and are therefore not to be considered limiting of its scope, for the invention may admit to other equally effective embodiments.

FIG. 1 is a schematic view of an exemplary etching chamber for use with the processes described herein;

FIG. 2 is a flow chart illustrating a sequence for processing a substrate according to one embodiment of the invention;

FIGS. 3A-3F are cross sectional views showing an etching sequence of one embodiment of the invention.

### DETAILED DESCRIPTION OF THE PREFERRED EMBODIMENT

Aspects of the invention will be described below in reference to an inductively coupled plasma etch chamber. Suitable inductively coupled plasma etch chamber include the ETEC Tetra™ photomask etch chamber available from ETEC of Hayward, Calif., or optionally, the Decoupled Plasma Source (DPS™) chamber available from Applied Materials, Inc., of Santa Clara, Calif. Other process chambers may be used to perform the processes of the invention, including, for example, capacitive coupled parallel plate chambers and magnetically enhanced ion etch chambers as well as inductively coupled plasma etch chambers of different designs. Although the processes are advantageously performed with the ETEC Tetra™ photomask etch chamber, the description in conjunction with the DPS™ processing chamber is illustrative, and should not be construed or interpreted to limit the scope of aspects of the invention.

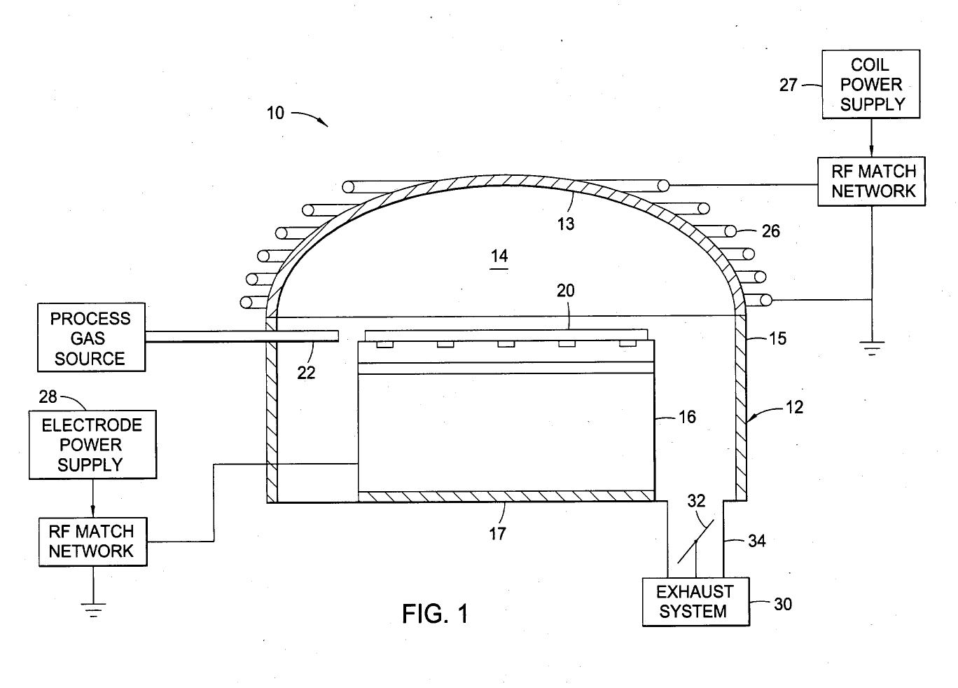

FIG. 1 is a schematic cross sectional view of one embodiment of a DPS™ processing chamber that may be used for performing the processes described herein. The processing chamber 10 generally includes a cylindrical sidewall or chamber body 12, an energy transparent dome ceiling 13 mounted on the body 12, and a chamber bottom 17. An inductive coil 26 is disposed around at least a portion of the dome 13. The chamber body 12 and the chamber bottom 17 of the processing chamber 10 can be made of a metal, such as anodized aluminum, and the dome 13 can be made of an energy transparent material such as a ceramic or other dielectric material.

A substrate support member 16 is disposed in the processing chamber 10 to support a substrate 20 during processing. The support member 16 may be a conventional mechanical or electrostatic chuck with at least a portion of the support member 16 being electrically conductive and capable of serving as a process bias cathode. While not shown, a reticle adapter may be used to secure the reticle on the support member 16. The reticle adapter generally includes a lower portion milled to cover an upper portion of the support member and a top portion having an opening that is sized and shaped to hold a reticle. A suitable reticle adapter is disclosed in U.S. Pat. No. 6,251,217, issued on Jun. 26, 2001, which is incorporated herein by reference to the extent not inconsistent with aspects and claims of the invention.

Processing gases are introduced into the processing chamber 10 from a process gas source (not shown) through a gas distributor 22 peripherally disposed about the support member 16. Mass flow controllers (not shown) for each processing gas, or alternatively, for mixtures of the processing gas, are disposed between the processing chamber 10 and the process gas source to regulate the respective flow rates of the process gases. The mass flow controllers can regulate up to about 1000 sccm flow rate for each processing gas or processing gas mixture.

A plasma zone 14 is defined by the process chamber 10, the substrate support member 16 and the dome 13. A plasma is formed in the plasma zone 14 from the processing gases using a coil power supply 27 which supplies power to the inductor coil 26 to generate an electromagnetic field in the plasma zone 14. The support member 16 includes an electrode disposed therein, which is powered by an electrode power supply 28 and generates a capacitive electric field in the processing chamber 10. Typically, RF power is applied to the electrode in the support member 16 while the body 12 is electrically grounded. The capacitive electric field is transverse to the plane of the support member 16, and influences the directionality of charged species more normal to the substrate 20 to provide more vertically oriented anisotropic etching of the substrate 20.

Process gases and etchant byproducts are exhausted from the process chamber 10 through an exhaust system 30. The exhaust system 30 may be disposed in the bottom 17 of the processing chamber 10 or may be disposed in the body 12 of the processing chamber 10 for removal of processing gases. A throttle valve 32 is provided in an exhaust port 34 for controlling the pressure in the processing chamber 10. An optical endpoint measurement device can be connected to the processing chamber 10 to determine the endpoint of a process performed in the chamber.

While the following process description illustrates one embodiment of etching a substrate by the processing gases described herein, the invention contemplates the use of processing parameters outside the ranges described herein for performing this process in different apparatus, such as a different etching chamber, and for different reticle sizes, such as a photolithographic reticle suitable for 9 inch substrate processing.

Exemplary Etch Process

An attenuating material, for example, a silicon based material including molybdenum silicide (MoSi) or molybdenum silicon oxynitride (MoSiON), used in manufacturing photomasks is etched to produce features having straight vertical sidewall definition with sharp angled profiles and a flat feature bottom. The processing gas used in etching the optically transparent material includes (i) one or more fluorine containing hydrocarbon gases, (ii) a chlorine containing gas, and optionally, (iii) an inert gas.

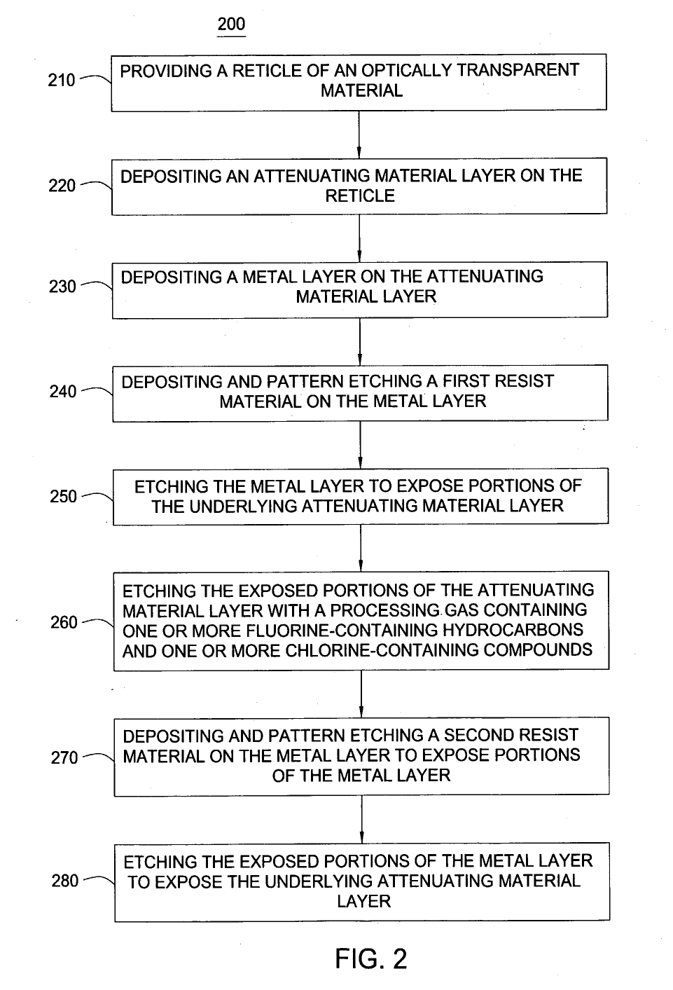

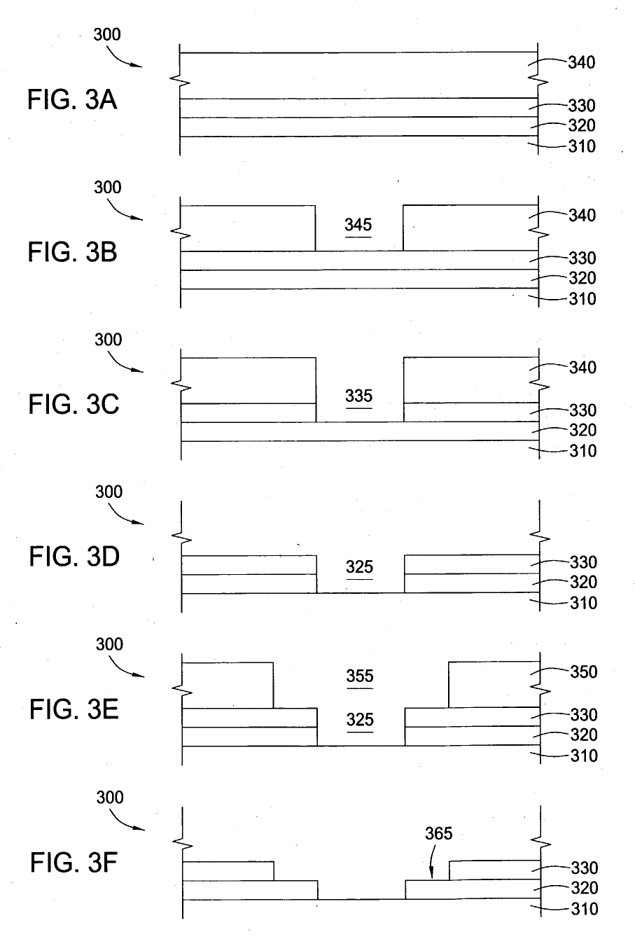

FIG. 2 shows a flow chart of one embodiment of an etching process 200 with the processing gas described herein. FIGS. 3A-3F are cross sectional views showing an etching sequence of one embodiment of the invention as described in process 200. The flow chart is provided for illustrative purposes and should not be construed as limiting the scope of aspects of the invention.

A substrate is provided to a processing chamber at step 210, such as the DPS™ processing chamber 10 of FIG. 1. Referring to FIG. 3A, the reticle 300 comprise a base material of an optically transparent material 310, for example, optical quality quartz, calcium fluoride, alumina, sapphire, or combinations thereof, typically made of optical quality quartz material.

An attenuating material layer 320 is then deposited on the optically transparent material 310 at step 220. The attenuating material may include molybdenum silicide, molybdenum silicon oxynitride (MoSiₓN_{y}O_{z}), combinations thereof, or any other material known or unknown that may modify or shift the phase of light passing therethrough. The attenuating material may shift the phase of light passing therethrough 180°, which phase shift of the light is believed to cause an interference with the light being transmitted and result in a cancellation of light and reduction in the detraction of the light passing therethrough. Typically, between about 5% and about 18% of the light is transmitted through the phase attenuating material. The attenuating material may be used to modify light used in photolithographic processes, such as light wavelengths of 248 nm and 193 nm.

The attenuating material may be deposited between about 50 nm and about 100 nm thick, but the thickness of the material layer may be greater or smaller based upon the process requirements, for example, the amount or type of illumination being used as a source of light passing therethrough. The attenuating material layer may be deposited by conventional methods known in the art, such as by chemical vapor deposition (CVD) techniques.

The substrate is then processed by depositing an opaque, conformal metal layer as a photomask layer on the substrate at step 230. A photomask layer 330 of a metal, for example, chromium, is deposited on the attenuating material layer 320 as shown in FIG. 3A. The metal layer may be deposited by conventional methods known in the art, such as by physical vapor deposition (PVD) or chemical vapor deposition (CVD) techniques. The metal layer 330 is typically deposited to a thickness between about 50 and about 100 nanometers (nm) thick, however, the depth of the layer may change based upon the requirements of the manufacturer and the composition of the materials of the substrate or metal layer. The invention does contemplate the use of other materials, such as non-metal inorganic or organic materials, as photomask layers for use in the processes described herein.

The feature dimensions to be formed in the metal layer are patterned by depositing, developing, and pattern etching a first resist material 340 at step 240 to form resist feature definitions 345 that expose the conformal metal layer 330 as shown in FIG. 3B. The resist materials used in photolithographic reticle fabrication are usually low temperature resist materials, which is defined herein as materials that thermally degrade at temperatures above about 250° C. Resist material may be patterned optically, i.e., photoresist materials, or by another radiative energy patterning device, such as an ion beam emitter or as e-beam resist materials. The layer of resist material 340, such as photoresist “RISTON,” manufactured by duPont de Nemours Chemical Company, is deposited on the metal layer 330 to a thickness between about 200 and 600 nm thick. The resist material 340 is then pattern etched using conventional laser or electron beam patterning equipment to form features 345 to define the dimensions of the features to be formed in the metal layer 330 and attenuating material layer 320.

Feature definitions 335 are then formed in the substrate by etching the conformal metal layer 330 at step 250 to expose the underlying attenuating material layer 320 as shown in FIG. 3C. Feature definitions 335 are etched in one embodiment by transferring the substrate 300 to an etch chamber and the metal layer 330 is etched using metal etching techniques known in the art or by new metal etching techniques that may be developed. One example of a metal etch process is more fully described in U.S. patent application Ser. No. 10/024,958, filed on Dec. 18, 2001, and entitled “Etch Process For Photolithographic Reticle Manufacturing With Improved Etch Bias”, which is incorporated herein by reference to the extent not inconsistent with claimed aspects and disclosure herein. The metal layer 330 may be etched in one or more process steps.

After etching of the metal layer 330 is completed, the remaining photoresist material 340 is removed from the substrate 300, such as by an oxygen plasma process, or other resist removal technique known in the art. The resist material removal step is optional and may be retained on the substrate during subsequent etching.

The attenuating material layer 320 may then be etched by a processing gas including (i) one or more fluorine containing polymerizing materials, (ii) a chlorine containing gas, and optionally, (iii) an inert gas, to form feature definition 325 at step 260 as shown in FIG. 3D. A polymerization limiting or inhibiting gas may also be included in the processing gas. To perform the etch process, the substrate 300 is then transferred to a DPS™ processing chamber where the processing gas is introduced into the processing chamber and a plasma is generated.

The one or more fluorine containing polymerizing materials may include one or more fluorine containing hydrocarbons, hydrogen free fluorine containing gases, or combinations thereof. The one or more fluorine containing hydrocarbons have the general formula C_{X}H_{Y}F_{Z}, wherein x is an integer from 1 to 5 of carbon atoms, y is an integer from 1 to 8 of hydrogen atoms, and z is an integer from 1 to 8 of fluorine atoms. Examples of fluorine containing hydrocarbon gases include CHF₃, CH₃F, CH₂F₂, C₂HF₅, C_{2H}₄F₂, and combinations thereof. Fluorine containing hydrocarbon gases having from 1 to 2 atoms of carbon, from 1 to 4 atoms of hydrogen, and from 1 to 5 atoms of fluorine, such as CHF₃, are preferably used when etching the optically transparent material.

The hydrogen free fluorocarbons can have from 1 to 5 atoms of carbon and from 4 to 8 atoms of fluorine. Examples of hydrogen free fluorocarbon gases include CF₄, C₂F₆, C₄F₆, C₃F₈, C₄F₈, C₅F₈, and combinations thereof Optionally, the processing gas may include additional etching gases for example, sulfur fluorides, such as sulfur hexafluoride (SF₆).

Fluorine containing polymerizing materials are advantageously used to form passivating polymer deposits on the surfaces, particularly the sidewalls, of feature definitions formed in a patterned resist material and etched optically transparent materials. The passivating polymer deposits prevent excessive etching of the feature definitions, thereby producing feature definitions having desired critical dimensions. A plasma of the one or more fluorine containing hydrocarbons produces fluorine-containing species that etch the attenuating material 320 on the substrate 300 without the presence of an oxidizing gas.

The chlorine-containing gases are selected from the group of chlorine (Cl₂), carbon tetrachloride (CCl₄), hydrochloric acid (HCl), and combinations thereof, of which Cl₂ is preferred, and are used to supply highly reactive radicals to etch the optically transparent material. The chlorine-containing gas provides a source of etching radicals and hydrogen or carbon-containing chlorine-containing gases may provide a source of material for forming passivating polymer deposits, which may improve etch bias.

The processing gas may also include an inert gas which, when ionized as part of the plasma comprising the processing gas, results in sputtering species to increase the etching rate of the feature definitions. The presence of an inert gas as part of the plasma may also enhance dissociation of the processing gas. Additionally, inert gases added to the process gas form ionized sputtering species and may further sputter-off any formed polymer deposits on the sidewalls of the freshly etched feature definitions, thereby reducing any passivating deposits and providing a controllable etch rate. It has been observed that the inclusion of an inert gas into the processing gas provides improved plasma stability and improved etching uniformity. Examples of inert gases include argon (Ar), helium (He), neon (Ne), xenon (Xe), krypton (Kr), and combinations thereof, of which argon and helium are generally used.

In one example, the processing gas comprises chlorine (Cl₂) gas, trifluoromethane (CHF₃), and argon as an inert gas. Optionally, the processing gas may include one or more polymerization limiting gases, such as oxygen, ozone, nitrogen, or combinations thereof, may be used to control the etching rates of the processing gas by controlling the formation and removal of passivating polymer deposits on the substrate. Oxygen containing gases enhance the formation of free oxygen species that react with other species to reduce the formation of polymers that deposit on the surfaces of the etched feature definitions as passivating deposits. For example, oxygen gases react with some of the radicals of the plasma process, such as CF₂, to form volatile radicals, such as COF₂, which are exhausted from the processing chamber.

The total flow rate of the processing gases, including the inert gas and optional gases, are introduced at a flow rate of greater than about 15 sccm, such as between about 15 sccm and about 200 sccm for etching a 150 mm by 150 mm square photolithographic reticle in an etch chamber. The chlorine-containing gas is introduced into the processing chamber at a flow rate of between about 5 sccm and about 100 sccm for etching a 150 mm by 150 mm square photolithographic reticle. When the fluorine containing polymerizing materials is introduced into the processing chamber, a flow rate between about 1 sccm and about 50 sccm is used for etching a 150 mm by 150 mm square photolithographic reticle. When the inert gas is introduced into the processing chamber, a flow rate between about 0 sccm and about 100 sccm is used for etching a 150 mm by 150 mm square photolithographic reticle. Optionally, when polymerization limiting gases are introduced into the processing chamber, a flow rate between about 1 sccm and about 100 sccm is used for etching a 150 mm by 150 mm square photolithographic reticle.

The individual and total gas flows of the processing gases may vary based upon a number of processing factors, such as the size of the processing chamber, the size of the substrate being processed, and the specific etching profile desired by the operator.

Generally, the processing chamber pressure is maintained between about 2 milliTorr and about 50 milliTorr. A chamber pressure between about 3 milliTorr and about 20 milliTorr, for example, 3 milliTorr and 10 milliTorr, may be maintained during the etching process.

The substrate is generally maintained at a temperature of about 150° C. or less during processing. A substrate temperature of about 150° C. or less has been observed to have minimal heat degradation of materials, such as resist materials, deposited on the substrate during the photolithographic reticle fabrication processes with the processing gases described herein. A substrate temperature between about 20° C. and about 150° C., preferably between about 20° C. and about 50° C., may be used to etch photomask feature definitions with minimal heat degradation of material disposed on the substrate surface. It is also believed that the substrate temperature that limit polymerization reactions during the etching process helps regulate the formation of passivating polymer deposits. Additionally, the sidewalls of the processing chamber are maintained at a temperature of less than about 70° C. and the dome is maintained at a temperature of less than about 80° C. to maintain consistent processing conditions and to minimize polymer formation on the surfaces of the processing chamber.

Generally, a source RF power level of about 1000 Watts or less is applied to an inductor coil to generate and sustain a plasma of the processing gases during the etching process. A power level between about 200 Watts and about 1000 Watts, such as between about 250 Watts and about 500 Watts, has been observed to provide sufficient plasma of the processing gases sufficient for etching the substrate surface. The recited source RF power levels have been observed to produce sufficient etching radicals and polymerization radicals from the processing gases to etch the exposed optically transparent material disposed on the substrate while providing a sufficiently low power level compared to prior art metal etch processes at substrate temperatures of about 150° C. or less.

Generally, a bias power of less than about 500 Watts, for example about 200 Watts or less, is applied to the substrate to increase directionality of the etching radicals with respect to the surface of the substrate. A bias power of less than 75 Watts, such as between about 10 Watts and about 70 Watts, may be used in the etching process to accelerate the speed of the etching radicals and provide more directionality of the etching radicals with respect to the surface of the substrate, thereby producing a more anisotropic etch. In one embodiment of the process described herein, the RF source power is applied at a power level of about 200 Watts or higher and the bias power is applied at power level of about 200 Watts or less.

The exposed attenuating material may be etched by the plasma of the processing gases for between about 15 seconds and about 300 seconds, for example, between about 30 seconds and about 270 seconds. The attenuating material may be exposed to the plasma of the processing gas for between about 10 seconds and about 270 seconds, for example between about 90 seconds and about 205 seconds.

Alternatively, an overetch step may be performed after each etching process of the materials described herein to ensure removal of all of the desired material from the substrate. In one aspect, the overetch may use the same processing gases and processing conditions for an additional period of time. The overetch process may be performed for an additional period of time between about 10% and about 60%, such as between about 25% and about 50%, of the etching time of the optically transparent material.

The etching process as described herein was also observed to remove “top”, or upper surface resist material, independent of “side”, or within feature resist material, which is consistent with anisotropic etching and improved feature formation. Additionally, processed substrates have produced feature definitions with the desired critical dimension with an almost vertical profile, i.e., an angle of about 90° between the sidewall of the feature and the bottom of the feature compared to prior art result of about 85°to about 88°.

Further, it is contemplated that the etch chemistry and the processing conditions may also be used to etch dielectric layers containing silicon, such as silicon oxide, titanium silicide, and silicon nitride, as well as other silicon based materials, such as undoped silicate glass, phosphosilicate glass, and borophosphatesilicate glass, which are used in semiconductor manufacturing.

Referring back to FIG. 3D, the above described processing regimes will etch the attenuating material 320 to define feature definitions 325 of the photomask. The phase shift feature definitions 325 formed by this process have straight sidewalls, flat, even bottoms, and high profile angles. Once the etching of the attenuating material 320 is finished, the remaining resist material 350 surrounding the feature definitions 325 is removed, such as by an oxygen plasma or other resist removal technique known in the art.

The metal layer 330 may then be etched to exposed underlying attenuating material layer 320 by first depositing, developing, and pattern etching a second photoresist material 350 to expose the underlying metal layer 330 defining the feature definitions 325 at step 270 as shown in FIG. 3E. The second photoresist material 350 is patterned to a metal feature definition 355 for etching the metal layer 330. The photoresist material 350 is deposited to a depth of about 200 nm thick, but may be of any thickness and is preferably of at least the same thickness as the depth of the feature definitions to be etched in the metal layer 330 to form the photolithographic reticle.

Exposed portions of the metal layer 330 may then be etched as described herein for metal etching to expose underlying portions of the attenuating material layer 320 at step 280 and shown in FIG. 3F. The etched metal then defines phase shift feature 365, which modify the phase of light passing therethough as stated herein to reduce detraction and improve resolution in forming feature definitions with photolithographic processes. An overetch process may be used to ensure complete removal of metal layer 330 material from the attenuating phase material 320. The second photoresist material 350 may be stripped as described herein to form an attenuating phase shift photolithographic reticle.

### EXAMPLES

In one broad example of the processes described herein, chlorine gas is introduced into the processing chamber at a flow rate between about 15 sccm and about 50 sccm and trifluoromethane (CHF₃) is introduced into the processing chamber at a flow rate between about 1 sccm and about 35 sccm during the etching process to etch a MoSi layer. Optionally, argon is introduced into the processing chamber at a flow rate between about 25 sccm and about 100 sccm.

Generally, the processing chamber pressure is maintained between about 2 milliTorr and about 30 milliTorr, for example about 3 milliTorr or about 10 milliTorr. A source RF power between about 250 Watts and about 500 Watts is applied to an inductor coil to generate and sustain a plasma of the processing gases during the etching process. A bias power between about 10 Watts and about 100 Watts, for example about 13 Watts or about 70 Watts, is applied to the substrate support. The etching process is performed between about 30 seconds and about 180 seconds. The overetch may be performed for between about 10% and about 55% of the time of the original etch process.

The substrate temperature is between about 20° C. and about 100° C. during the etching process. Additionally, the sidewalls 15 of the processing chamber 10 are maintained at a temperature of about less than about 70° C. and the dome is maintained at a temperature of less than about 80° C. Under the above described processing regime parameters, the MoSi material 320 can be etched at a rate between about 100 Å/min and about 1000 Å/min depending on the composition of the processing gas and construction of the processing chamber.

In another example of one embodiment of the invention, a processing gas comprising Cl₂ and CHF₃ was introduced into a processing chamber at flow rates of about 25 sccm and about 25 sccm, respectively, and the processing chamber is maintained at a pressure of about 3 Torr. A source RF power of about 400 Watts is applied to an inductor coil to generate and sustain the plasma during the process with a bias power of about 70 Watts applied to the substrate support to enhance control of the etching process. The substrate is maintained at a temperature between about 50° C. and about 80° C. with the sidewalls of the processing chamber maintained at a temperature of about 70° C. and the dome is maintained at a temperature of about 80° C. An over etch of 50% was performed after the original etch.

It has been observed that the etch rates of the MoSi and photoresist decrease with increasing CHF₃ concentrations, and that has been observed that the selectivity of MoSi to photoresist increases with increasing CHF₃ concentrations.

In another example, a photolithographic reticle including a substrate made of an attenuating material molybdenum silicide (MoSi) with a chromium photomask layer approximately 100 nanometers (nm) thick disposed thereon is introduced into a processing chamber for resist deposition. A resist, such as ZEP, a resist material commercially available from Tokyo-Oka of Japan, or a chemically amplified resist or CAR resist also commercially available from Tokyo-Oka of Japan, is deposited upon the chromium oxynitride layer and then patterned using conventional laser or electron beam patterning equipment. The resist deposited on the substrate is between about 200 nm and about 600 nm thick, for example, between about 300 nm and about 400 nm thick, but may be of any thickness desired. The chromium layer is etched to expose the MoSi material and the remaining photoresist is removed. A second resist layer is deposited and patterned to expose the MoSi material.

The prepared substrate was then introduced into a DPS™ plasma etching chamber. A pre-cleaning step was performed on the substrate to remove processing contaminants prior to the etching process by introducing oxygen gas at a flow rate of about 30 sccm into the chamber maintained at a chamber pressure of about 10 milliTorr and striking a plasma at about 200 Watt for about 60 seconds.

The reticle is placed in an etch chamber such as the DPS™ metal etch chamber described above. The patterned substrate described above is placed on the cathode pedestal of the etch chamber, and the chamber was maintained at a pressure of about 3 milliTorr. A plasma was generated by applying a source RF voltage to the inductor coil at a power level of about 400 Watts. A bias power of about 70 Watts was applied to the cathode pedestal. The etching of the MoSi material occurred for approximately 70 seconds under a total flow of 50 sccm with the following gas flows:

| | |
|---|---|
| Trifluoromethane (CHF₃), at | 25 sccm, and |
| Chlorine gas (Cl₂), at | 25 sccm. |

While foregoing is directed to the preferred embodiment of the invention, other and further embodiments of the invention may be devised without departing from the basic scope thereof, and the scope thereof is determined by the claims that follow.

What is claimed is:

1. A method for processing a photolithographic reticle, comprising:
positioning the reticle on a support member in a processing chamber, wherein the reticle comprises an attenuating material layer disposed on an optically transparent material, a patterned metal photomask layer formed on the attenuating material layer, and a patterned resist material deposited on the patterned metal photomask layer;
introducing a processing gas comprising one or more fluorine containing polymerizing materials and one or more chlorine-containing gases into the processing chamber;
delivering power to the processing chamber to generate a plasma by applying a source RF power to a coil and applying a bias power to the support member; and
etching exposed portions of the attenuating material layer.

2. The method of claim 1, wherein the attenuating material layer is selected from the group of molybdenum silicide (MoSi), molybdenum silicon oxynitride (MoSiON), and combinations thereof.

3. The method of claim 1, wherein the one or more fluorine containing polymerizing materials include fluorine containing hydrocarbons having the formula C_{X}H_{Y}F_{Z}, where x is an integer from 1 to 5, y is an integer from 1 to 8, and z is an integer from 1 to 8.

4. The method of claim 3, wherein the one or more fluorine containing hydrocarbons having the formula C_{X}H_{Y}F_{Z} are selected from the group of CHF₃, CH₃F, CH₂F₂, C₂HF₅, C₂H₄F₂, and combinations thereof.

5. The method of claim 1, wherein the plasma is generated by applying the source RF power to the coil between about 200 Watts and about 1000 Watts and by applying the bias power between about 10 Watts and about 200 Watts.

6. The method of claim 1, wherein the chlorine containing gas is selected from the group of chlorine (Cl₂), hydrochloric acid (HCl), silicon tetrachloride (SiCl₄), boron trichloride (BCl₃), and combinations thereof.

7. The method of claim 1, wherein the processing gas further comprises an inert gas selected from the group of argon, helium, and combinations thereof.

8. The method of claim 1, wherein processing the photolithographic reticle comprises introducing one or more fluorine containing hydrocarbons selected from the group of CHF₃, CH₃F, CH₂F₂, C₂HF₅, C₂H₄F₂, and combinations thereof, at a flow rate between about 5 sccm and about 100 sccm, introducing a chlorine containing gas selected from the group of Cl₂, HCl, SiCl₄, BCl₃, and combinations thereof, at a flow rate between about 5 sccm and about 100 sccm, introducing an inert gas selected from the group of helium, argon, xenon, neon, krypton, and combinations thereof, at a flow rate between about 0 sccm and about 100 sccm into a processing chamber, maintaining the processing chamber at a pressure between about 2 milliTorr and about 25 milliTorr, maintaining the substrate at a temperature between about 50° C. and about 150° C., and generating a plasma by applying a source RF power between about 250 Watts and about 700 Watts to the processing chamber and applying a bias power to the support member between about 10 Watts and about 200 Watts.

9. The method of claim 1, wherein the processing gas further comprises a fluorine containing gas selected from the group of fluorocarbons, SF₆, and combinations thereof.

10. The method of claim 1, further comprising etching the metal photomask layer to expose underlying attenuating material layer by depositing and pattering a second photoresist material on the metal photomask layer to expose a portion of the metal photomask layer and etching the exposed metal photomask layer.

11. A method for etching a reticle comprising an attenuating material layer disposed on an optically transparent material, a patterned metal photomask layer formed on attenuating material layer, and a patterned resist material deposited on the patterned metal photomask layer, the method comprising:
placing the reticle in a processing chamber on a support member, wherein the reticle is maintained at a temperature of less than about 150° C.;
introducing a processing gas comprising one or more fluorine containing hydrocarbons have the formula C_{X}H_{Y}F_{Z}, where x is an integer from 1 to 5, y is an integer from 1 to 8, and z is an integer from 1 to 8 and chlorine gas;
delivering power to the processing chamber to generate a plasma; and
etching exposed portions of the attenuating material layer.

12. The method of claim 11, wherein the attenuating material layer is selected from the group of molybdenum silicide (MoSi), molybdenum silicon oxynitride (MoSiON), and combinations thereof.

13. The method of claim 11, wherein the wherein the one or more fluorine containing hydrocarbons having the formula C_{X}H_{Y}F_{Z} are selected from the group of CHF₃, CH₃F, CH₂F₂, C₂HF₅, C₂H_{4F}₂, and combinations thereof.

14. The method of claim 11, wherein the delivering power to the processing chamber comprises applying a source RF power of about 200 Watts or more to a coil and applying a bias power to the support member of about 200 Watts or less to generate a plasma.

15. The method of claim 14, wherein the source RF power is applied at between about 200 Watts and about 1000 Watts.

16. The method of claim 14, wherein the bias power is applied to the support member at between about 10 Watts and about 200 Watts.

17. The method of claim 11, wherein the processing gas further comprises an inert gas selected from the group of argon, helium, and combinations thereof.

18. The method of claim 11, wherein the one or more fluorine containing hydrocarbons have the formula C_{X}H_{Y}F_{Z} are introduced into the processing chamber at a flow rate between about 5 sccm and about 100 sccm, the chlorine gas is introduced into the processing chamber at a flow rate between about 5 sccm and about 100 sccm, and an inert gas is introduced into the processing chamber at a flow rate between about 0 sccm and about 100 sccm, and further comprising generating a plasma in the processing chamber maintained at a pressure between about 2 milliTorr and about 50 milliTorr with the reticle maintained at a temperature between about 50° C. and about 150° C. by applying a RF power between about 200 Watts and 1000 Watts and applying a bias power to the support member between about 10 Watts and about 200 Watts.

19. The method of claim 11, wherein the processing gas further comprises a fluorine containing gas selected from the group of fluorocarbons, SF₆, and combinations thereof.

20. The method of claim 11, further comprising etching the metal photomask layer to expose underlying attenuating material layer by depositing and pattering a second photoresist material on the metal photomask layer to expose a portion of the metal photomask layer and etching the exposed metal photomask layer.

21. A method for fabricating a reticle for a photolithographic processing, comprising:
patterning a metal layer disposed on an attenuating material layer to expose the attenuating material layer;
depositing and patterning a resist layer over the patterned metal layer to expose the attenuating material layer;
placing the photomask on a support member in an etch processing chamber;
introducing a processing gas comprising one or more fluorine containing polymerizing materials and one or more chlorine-containing gases into the processing chamber;
applying a source of RF power to a coil disposed adjacent the etch processing chamber to generate a plasma in the processing chamber; and
etching exposed portions of the attenuating material layer.

22. The method of claim 21, wherein the attenuating material layer is selected from the group of molybdenum silicide (MoSi), molybdenum silicon oxynitride (MoSiON), and combinations thereof.

23. The method of claim 21, wherein the one or more fluorine containing polymerizing materials include fluorine containing hydrocarbons having the formula C_{X}H_{Y}F_{Z}, where x is an integer from 1 to 5, y is an integer from 1 to 8, and z is an integer from 1 to 8.

24. The method of claim 23, wherein the one or more fluorine containing hydrocarbons having the formula C_{X}H_{Y}F_{Z} are selected from the group of CHF₃, CH₃F, CH₂F₂, C₂HF₅, C₂H₄F₂, and combinations thereof.

25. The method of claim 21, wherein the chlorine containing gas is selected from the group of chlorine (Cl₂), hydrochloric acid (HCl), silicon tetrachloride (SiCl₄), boron trichloride (BCl₃), and combinations thereof.

26. The method of claim 21, wherein the processing gas further comprises an inert gas selected from the group of argon, helium, and combinations thereof.

27. The method of claim 21, wherein the source RF power is between about 200 Watts and about 1000 Watts.

28. The method of claim 27, further comprising applying a bias power to the support member of about 200 Watts or less.

29. The method of claim 21, wherein the one or more fluorine containing hydrocarbons have the formula C_{X}H_{Y}F_{Z} are introduced into the processing chamber at a flow rate between about 5 sccm and about 100 sccm, the chlorine gas is introduced into the processing chamber at a flow rate between about 5 sccm and about 100 sccm, and an inert gas is introduced into the processing chamber at a flow rate between about 0 sccm and about 100 sccm, and further comprising generating a plasma in the processing chamber maintained at a pressure between about 2 milliTorr and about 50 milliTorr with the reticle maintained at a temperature between about 50° C. and about 150° C. by applying a RF power between about 50 Watts and 200 Watts and applying a bias power to the support member between about 10 Watts and about 200 Watts.

30. The method of claim 21, wherein the processing gas further comprises a fluorine containing gas selected from the group of fluorocarbons, SF₆, and combinations thereof.

31. The method of claim 21, further comprising etching the metal photomask layer to expose underlying attenuating material layer by depositing and pattering a second photoresist material on the metal photomask layer to expose a portion of the metal photomask layer and etching the exposed metal photomask layer.
